(19) United States
(12) Patent Application Publication
(10) Pub. No.: US 2010/0155819 A1
(43) Pub. Date: Jun. 24, 2010

(54) METHOD OF FABRICATING SEMICONDUCTOR DEVICE AND SEMICONDUCTOR DEVICE

(76) Inventors: Masayuki OGOSHI, Kuwana (JP); Tadashi SAGA, Yokkaichi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/564,823

(22) Filed: Sep. 22, 2009

(30) Foreign Application Priority Data
Dec. 22, 2008 (JP) 2008-325468

(51) Int. Cl. H01L 29/792; H01L 21/762

(52) U.S. Cl. 257/324; 438/427; 257/E21.546; 257/E29.309

(57) ABSTRACT

A method of fabricating a semiconductor device, includes forming an element isolation trench by processing a silicon substrate and a film to be processed, and filling the element isolation trench with an insulating film by a thermal CVD method. The thermal CVD method in filling the trench is executed under a film forming condition that the insulating film filling a part of the trench that is level with or is located lower than an upper surface of the silicon substrate has a porosity set so as to be not less than 5% and that the insulating film filling a part of the trench located higher than the upper surface of the silicon substrate has a lower deposition rate than the insulating film filling said part of the trench that is level with or is located lower than the upper surface of the silicon substrate.

### CROSS-REFERENCE TO RELATED APPLICATIONS

This application is based on and claims the benefit of priority from the prior Japanese Patent Application No. 2008-325468, filed on Dec. 22, 2008, the entire contents of which are incorporated herein by reference.

### BACKGROUND

1. Field

The present invention relates to a method of fabricating a semiconductor device having element isolation trenches which are filled with an insulating film by a thermal chemical vapor deposition (CVD) method, and the semiconductor device.

2. Related Art

Various techniques have been employed to fill narrow gaps such as element isolation trenches with an insulating film in the fabrication of semiconductor devices. The techniques include a thermal chemical vapor deposition (CVD) method, a high density plasma chemical vapor deposition (HDP-CVD) method, and a coating method. When narrow gaps are filled with an insulating film by the thermal CVD method, the insulating film is generally formed into a shape depending upon the shape of a base. Accordingly, the insulating film has a definite limitation in a filling characteristic. There is a problem that the insulating film has a difficulty particularly when the element isolation trench is formed into an inverted tapered sectional shape or has an overhang.

Furthermore, when active areas divided by the element isolation trenches are further structurally refined with high integration of semiconductor devices, stress due to an insulating film to fill the element isolation trenches is applied to active areas depending upon film-forming conditions of the thermal CVD method, whereupon the active areas would be deformed. As a result, there is a possibility that electrical characteristics of devices formed on the deformed active area may be deteriorated. Japanese patent application publication JP-2008-147414 discloses an example of configuration that an element isolation trench is filled with an insulating film by a thermal CVD method.

### SUMMARY

According to one aspect of the present invention, there is provided a method of fabricating a semiconductor device, comprising forming, on a silicon substrate, a film to be processed selected at least from a polysilicon film, an amorphous silicon film, a silicon oxide film and a silicon nitride film; forming an element isolation trench by processing the silicon substrate and the film to be processed; and filling the element isolation trench with an insulating film by a thermal chemical vapor deposition (CVD) method, wherein the thermal CVD method in filling the trench is executed under a film forming condition that the insulating film filling a part of the trench that is level with or is located lower than an upper surface of the silicon substrate has a porosity set so as to be not less than 5% and that the insulating film filling a part of the trench located higher than the upper surface of the silicon substrate has a lower deposition rate than the insulating film filling said part of the trench that is level with or is located lower than the upper surface of the silicon substrate.

According to another aspect of the present invention, there is provided a semiconductor device comprising a silicon substrate; a tunnel insulating film formed on the silicon substrate; a charge storage film formed on the tunnel insulating film; a plurality of element isolation trenches formed by processing the silicon substrate, the tunnel insulating film and the charge storage film; and an insulating film filling the element isolation trenches by a thermal chemical vapor deposition method, wherein the insulating film includes a first insulating film filling apart of the trenches that is level with or is located lower than an upper surface of the silicon substrate and a second insulating film filling a part of the trenches located higher than the upper surface of the silicon substrate; the second insulating film has a substantially uniform height from the upper surface of the silicon substrate between the element isolation trenches; and the first insulating film has a smaller density than the second insulating film.

### BRIEF DESCRIPTION OF THE DRAWINGS

FIG. 1 is a schematic sectional view of a semiconductor device in a step of the semiconductor device fabricating method in accordance with a first embodiment (No. 1);

FIG. 2 is a graph showing the relationship between a deposition temperature of a silicon oxide film and a distortion angle of an active area;

FIG. 3 is a graph showing the relationship between a TEOS flow rate during the forming of the silicon oxide film and a distortion angle of the active area;

FIG. 4 is a graph showing the relationship between an O₃ flow rate during the forming of the silicon oxide film and a distortion angle of the active area;

FIG. 5 is a graph showing the relationship between an H₂O flow rate during the forming of the silicon oxide film and a distortion angle of the active area;

FIG. 6 is a schematic sectional view of the semiconductor device in another step of the semiconductor device fabricating method (No. 2);

FIG. 7 is a schematic sectional view of the semiconductor device in further another step of the semiconductor device fabricating method (No. 3);

FIG. 8 is a schematic sectional view of the semiconductor device in further another step of the semiconductor device fabricating method (No. 4);

FIG. 9 shows the relationship between stress and a write time;

FIG. 10 is a schematic sectional view of the semiconductor device in a step of the semiconductor device fabricating method in accordance with a second embodiment (No. 1);

FIG. 11 is a schematic sectional view of the semiconductor device in another step of the semiconductor device fabricating method (No. 2);

FIG. 12 is a schematic sectional view of the semiconductor device in further another step of the semiconductor device fabricating method (No. 3);

FIG. 13 is a schematic sectional view of the semiconductor device in a step of the semiconductor device fabricating method in accordance with a third embodiment (No. 1);

FIG. 14 is a schematic sectional view of the semiconductor device in another step of the semiconductor device fabricating method (No. 2); and

FIG. 15 is a schematic sectional view of the semiconductor device in further another step of the semiconductor device fabricating method (No. 3).

### DETAILED DESCRIPTION

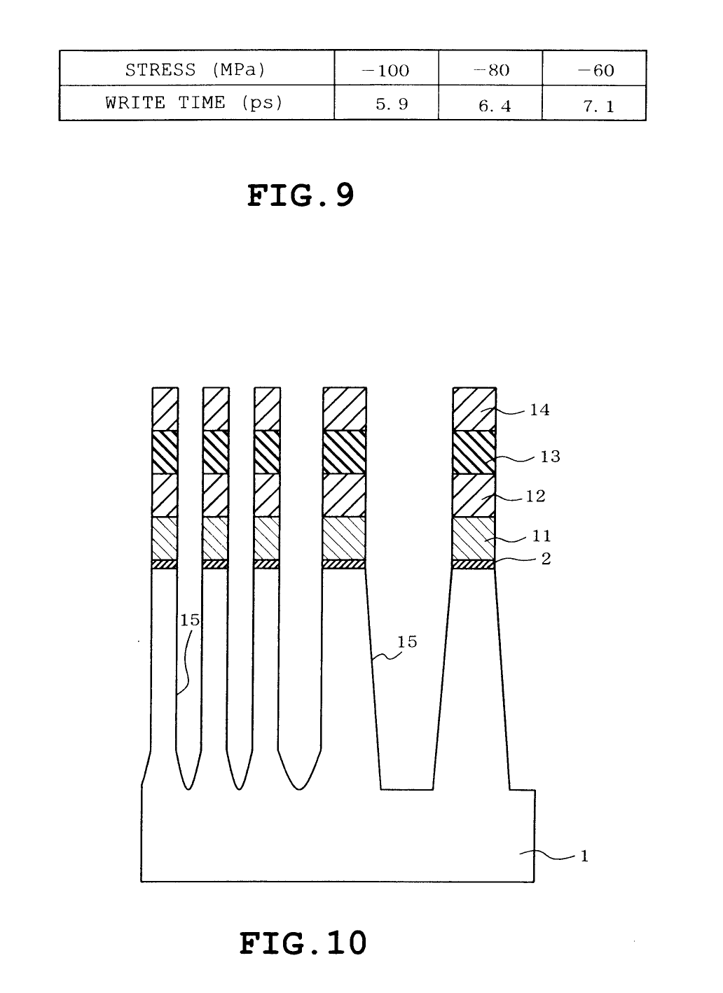

A first embodiment of the present invention will be described with reference to FIGS. 10 to 9. The first embodiment is directed to a flash memory with a structure of element isolation trenches each of which is filled with an insulating film. Identical or similar parts are labeled by the same reference numerals in the following description. The drawings typically illustrate the embodiments, and the relationship between a thickness and planar dimension, layer thickness ratio and the like differ from respective natural dimensions.

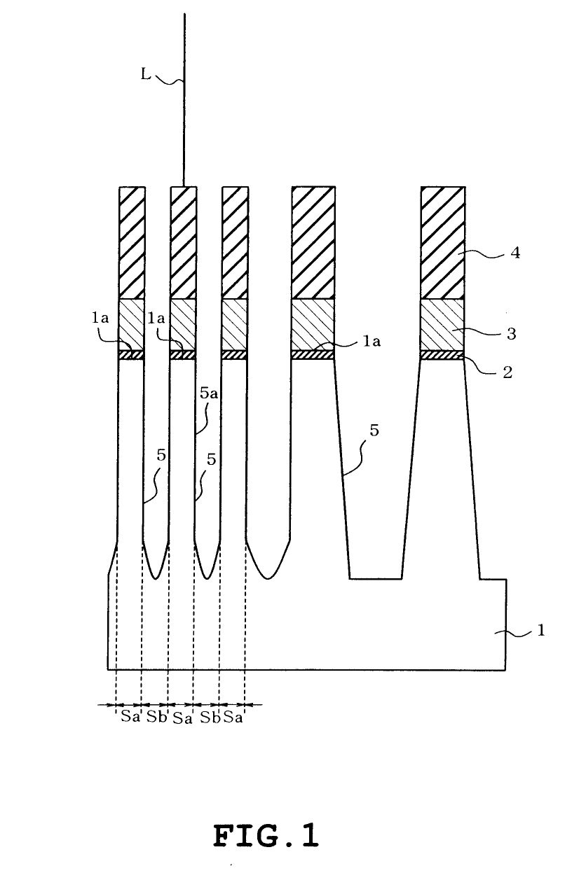

Firstly, a process of forming an element isolation trench of the flash memory will be described with reference to FIG. 1. As shown, a tunnel insulating film (a silicon oxide film) 2, a phosphor-doped polysilicon film 3 and a silicon nitride film 4 are sequentially formed on a silicon substrate 1. The polysilicon film 3 serves as a charge storage layer (a floating gate electrode), and the silicon nitride film 4 serves as a processing sacrificial film. In this case, the tunnel insulating film 2, the polysilicon film 3 and the silicon nitride film 4 constitutes a film to be processed. Subsequently, element isolation trenches 5 are formed by a lithography process and a reactive ion etching (RIE) process. In the above-described configuration, each active area Sa of a memory cell portion of the silicon substrate 1 has a width that is set so as to be not more than 40 nm, for example. Reference symbol “Sb” designates a width of an element isolation region (a shallow trench isolation (STI), for example) of the memory cell portion.

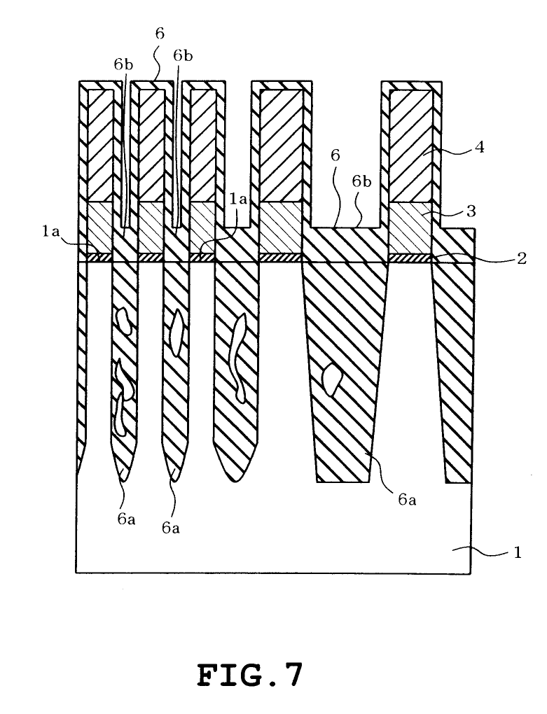

Subsequently, each element isolation trench 5 is filled with an insulating film such as a silicon oxide film by a thermal chemical vapor deposition (CVD) method. The following describes a specific deposition condition of the thermal CVD method. Tetraethoxysilane (TEOS), ozone O₃ and water vapor H₂O are used as material gases and have flow rates that are set to 0.6 g/min, 27 standard liter/minute (slm) and 8 g/min respectively. A deposition temperature is set to 350° C. A deposition time is adjusted so that each element isolation trench 5 in a region serving as a memory cell has a bottom that is level with or is located higher than an upper surface 1a of the silicon substrate 1 and further goes part of a height of the polysilicon film 3 (see FIG. 7).

The following experiment was conducted to specify the above-mentioned deposition condition of the silicon oxide film 6. Firstly, the deposition temperature and flow rates of TEOS, O₃ and H₂O were changed so that a distortion angle of the active area was changed. The distortion angle of the active area is an inclination angle of an inner side surface 5a of the element isolation trench 5 relative to line L (see FIG. 1) perpendicular to the upper surface of the silicon substrate 1. In this case, the distortion angle was measured from a scanning electron microscope (SEM) image (a sectional image of the element isolation trench imaged by an SEM).

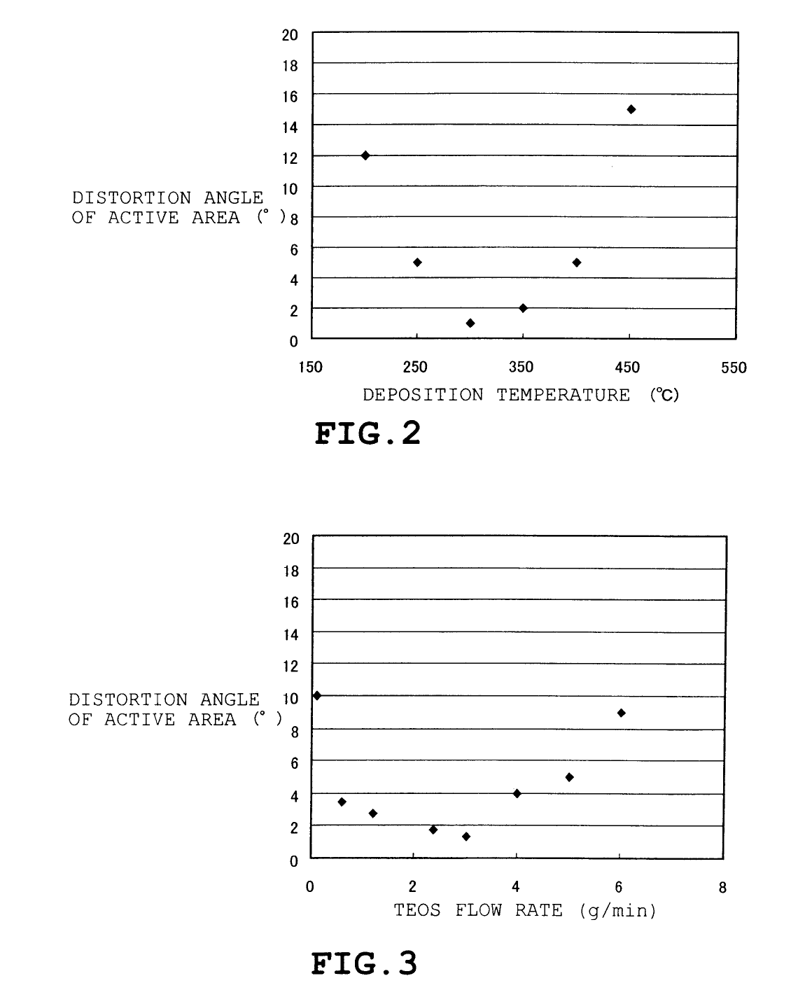

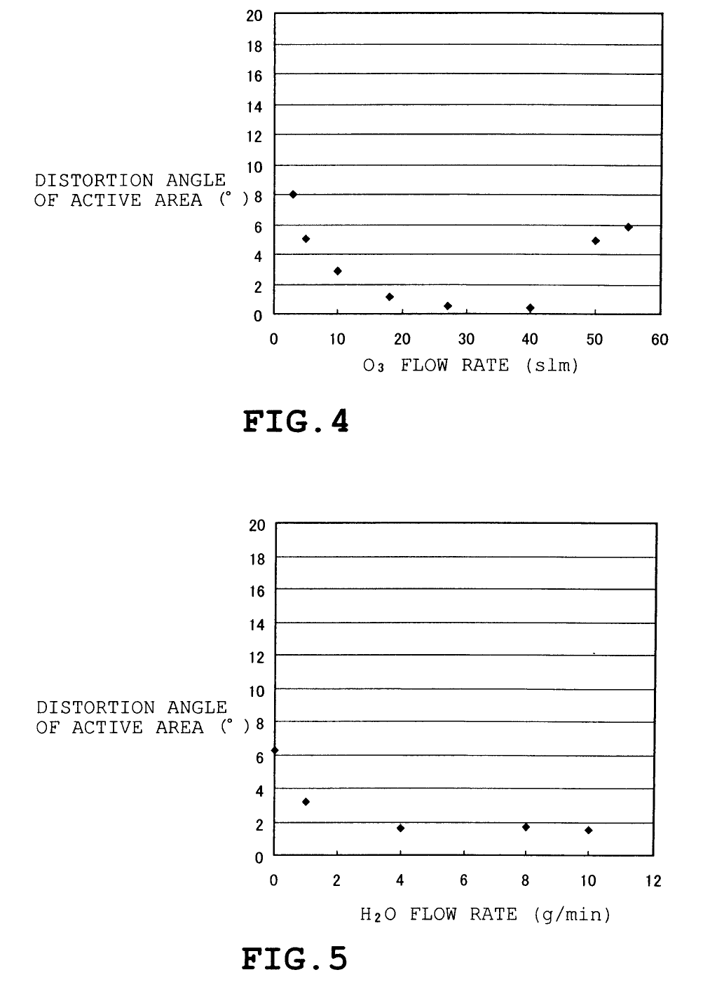

FIGS. 2 to 5 show the results of measurement of the distortion angle of the active area. FIG. 2 is a graph showing changes in the distortion angle of the active area in the case where a deposition temperature of the silicon oxide film 6 was changed. In this case, the flow rates of the TEOS, O₃ and H₂O were fixed to 4.8 g/min, 30 slm and 4 g/min respectively. Furthermore, FIG. 3 is a graph showing changes in the distortion angle of the active area in the case where the flow rate of the TEOS was changed. In this case, the deposition temperature was fixed to 300° C. and the flow rates of O₃ and H₂O were fixed to 30 slm and 4 g/min respectively. Furthermore, FIG. 4 is a graph showing changes in the distortion angle of the active area in the case where the flow rate of O₃ was changed. In this case, the deposition temperature was fixed to 300° C. and the flow rates of the TEOS and H₂O were fixed to 4.8 g/min and 4 g/min respectively. FIG. 5 is a graph showing changes in a distortion angle of the active area in the case where an H₂O flow rate is changed. In this case, the deposition temperature was fixed to 300° C. and the flow rates of the TEOS and O₃ were fixed to 4.8 g/min and 30 slm respectively.

Variations in an intercell threshold voltage caused malfunction in data writing and data erase when the distortion angle of the active area was larger than 5°. Accordingly, it can be understood that malfunction in data writing and data erase would not be caused when the distortion angle of the active area is not more than 5°. The inventors have found that deposition condition which sets the distortion angle of the active area to 5° C. or below includes a deposition temperature ranging from 250 to 400° C. (FIG. 2), the TEOS flow rate ranging from 0.3 to 5 g/min (FIG. 3), the O₃ flow rate ranging from 5 to 50 slm (FIG. 4) and H₂O flow rate of not less than 1 g/min (FIG. 5). In other words, the inventors have found that when the thermal CVD is carried out within the range of the above-described deposition condition, a thermal CVD film (a silicon oxide film) can be formed while the distortion of the active area is under control.

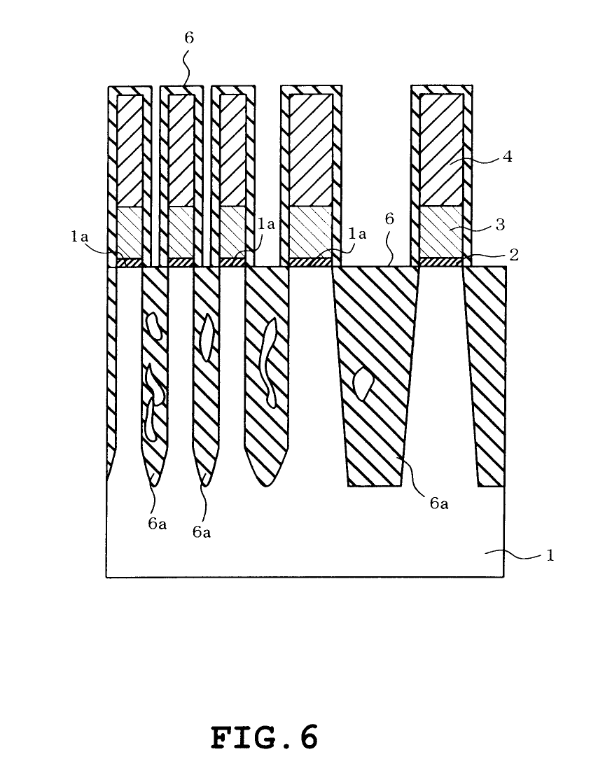

Of the film types exposed on the sidewall of the element isolation trench 5, a deposition rate is highest at the sidewall of the silicon substrate 1 as the result of employment of the aforementioned deposition condition, and the film deposited on the sidewall of the silicon substrate 1 has a rough surface, susceptibly reflecting variations in the surface state of the silicon substrate 1. When the element isolation trench is filled with the insulating film under this deposition condition, the material is uniform in a part of the inner surface of the element isolation trench 5 (silicon trench), which part is level with or is located higher than the upper surface 1a (see FIG. 6) of the silicon substrate 1. Accordingly, the silicon oxide film to fill the element isolation trench is deposited so as to be substantially uniform over the entire surface of the silicon substrate 1. In this case, since the surface of the silicon oxide film susceptibly reflects the non-uniformity in the surface state of the silicon substrate 1 thereby to become rough as described above, the silicon trench is not filled with the silicon oxide film completely and is filled with the silicon oxide film 6a with a porosity of about 10% (see FIG. 6).

On the other hand, the insulating film filling a part of the trench located higher than the upper surface 1a of the silicon substrate 1 has a lower deposition rate than the insulating film filling the part of the trench that is level with or is located lower than the upper surface 1a of the silicon substrate 1. As a result, a denser silicon oxide film 6b is formed, and the silicon oxide film 6b is deposited so as to have a substantially uniform height even when the plural element isolation trenches 5 differ from each other in the width or the cubic volume (see FIG. 7). A sufficient base selectivity of the silicon oxide film at the above-mentioned deposition rate is retained even when some native oxide is produced on the inner surface of the silicon trench.

Consequently, the silicon oxide film (a first insulating film) 6a having a higher porosity (about 10%, for example) is formed by the thermal CVD with the above-described deposition condition to fill the part of the trench 5 that is level with or is located lower than an upper surface of the silicon substrate (see FIG. 6). Thereafter, since the deposition rate is lower in the part of the silicon oxide film 6 that is located higher than the upper surface 1a of the silicon substrate 1, a silicon oxide film (a second insulating film) 6b is formed in the part of the trenches higher than the upper surface of the silicon substrate 1 so as to be denser (the porosity of substantially 0%, for example) than the silicon oxide film 6a (see FIG. 7). The porosity is here defined as a numeric value measured as a ratio of void to the section of element isolation trench 5 observed by a scanning electron microscope (SEM).

In each element isolation trench 5 filled in the above-described manner, a film stress is rendered smaller since the silicon oxide film 6a that is level with or is located higher than the upper surface 1a of the silicon substrate 1 has a small film density. Furthermore, since the heights of the silicon oxide film 6b from the upper surface 1a of the silicon substrate 1 are relatively even, stress applied to an element is canceled. Accordingly, when the mechanical strength is lowered or the element isolation trenches 5 differ in the shape due to refinement of the element, particularly controversial deformation of the active area can be suppressed.

Disequilibrium of stress applied to an active area results in a problem of deformation of the active area. However, a tensile stress of the film filling the element isolation trench distorts a semiconductor crystal lattice composing an active area, thereby improving the mobility of electrons. Accordingly, the semiconductor device which is fabricated so that stress applied to an active area is in disequilibrium achieves an advantage that a working speed of an N-type transistor is improved. Since a semiconductor memory device comprises cell transistors which are normally N-type transistors, a read/write speed of the semiconductor memory device can be improved. FIG. 9 shows variations in a write time (ps) in the case where the magnitude (in MPa) of applied stress is changed by changing the deposition condition of the thermal CVD film. According to FIG. 9, it can be understood that the write time becomes shorter, that is, a write speed becomes higher as the applied stress is large.

More specifically, it can be understood that the write speed is improved by stressing the active area thereby to produce distortion in the semiconductor crystal lattice composing the active area to the extent that an element is not deformed or broken. For example, a stress of −100 MPa is obtained under the conditions that a deposition temperature is at 375° C., a TEOS flow rate is 4.8 g/min, an O₃ flow rate is 30 slm and an H₂O flow rate is 4 g/min. Furthermore, a stress of −80 MPa is obtained under the conditions that a deposition temperature is at 350° C., a TEOS flow rate is 4.8 g/min, an O₃ flow rate is 30 slm and H₂O flow rate is 4 g/min. Additionally, a stress of −60 MPa is obtained under the conditions that a deposition temperature is at 325° C., a TEOS flow rate is 4.8 g/min, an O₃ flow rate is 30 slm and H₂O flow rate is 4 g/min.

A porosity of the thermal CVD film 6a formed so as to be level with or located lower than the upper surface of the silicon substrate was changed in the formation of the above-described thermal CVD film (a silicon oxide film) 6. This was accomplished by varying the conditions of the flow rate of the material gas, temperature or the like. In this case, when the porosity was less than 5%, the stress of the film was not rendered sufficiently small. Accordingly, it was found that there was a possibility of deformation in the active area with progress in structural refinement of the element. As a result, the porosity is set so as to be not less than 5%. Furthermore, the foregoing uniform deposition can be carried out when an upper limit of the porosity is about 25%.

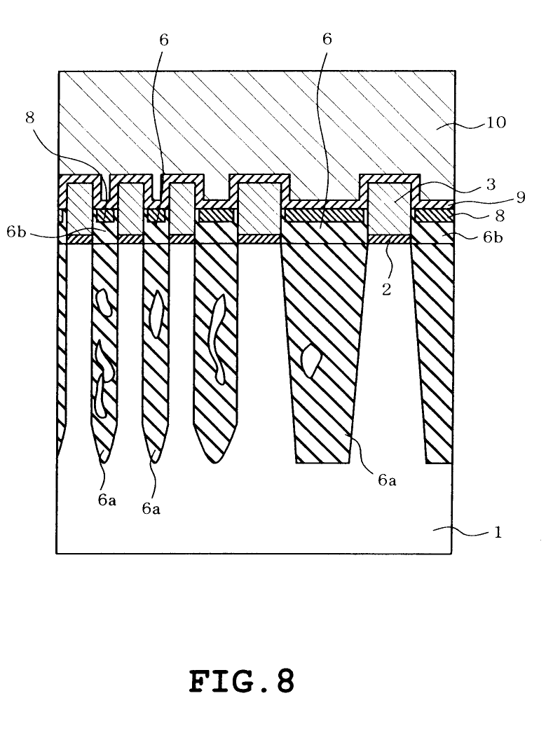

Element isolation trenches having larger opening widths in peripheral circuit regions are filled with insulating films after the element isolation trenches 5 in the memory cell regions have been filled with the insulating films as described above. In this case, the element isolation trenches are filled with polysilazane films by a coating method. Steam oxidation is carried out so that the polysilazane film is converted to a silicon oxide film 8, whereupon the filling of the element isolation trenches 5 is completed (see FIG. 8).

Although the polysilazane film is used to fill the element isolation trenches having larger opening widths, the trenches may be filled with a high density plasma (HDP) CVD film (a silicon oxide film) formed by an HDP-CVD method, instead.

Subsequently, planarization by a chemical mechanical polish (CMP) is carried out. The processing sacrificial film is removed by a wet treatment, and the element isolation region is etched back and other treatments are carried out. Furthermore, an interpoly insulating film 9 and a gate electrode 10 are formed as shown in FIG. 8. A diffusion layer, contact holes, a wiring layer and the like are consecutively formed, whereupon the semiconductor memory device is fabricated.

FIGS. 10 to 12 illustrate a second embodiment. In the second embodiment, identical or similar parts are labeled by the same reference symbols as those in the first embodiment. The second embodiment is directed to a flash memory (a MONOS type flash memory) having a different deposition structure of the gate electrode from the first embodiment. The flash memory has element isolation trenches each of which is filled with the insulating film.

Firstly, a process of forming an element isolation trench of the flash memory will be described with reference to FIG. 10. As shown, the tunnel insulating film 2 and a silicon nitride film 11 serving as a charge storage layer are formed on the silicon substrate 1 in turn. Furthermore, a silicon oxide film 12, a silicon nitride film 13 and a silicon oxide film 14 all serving as processing sacrificial films are sequentially formed on the silicon nitride film 11. Thereafter, element isolation trenches 15 are formed by a lithography process and a reactive ion etching (RIE) process.

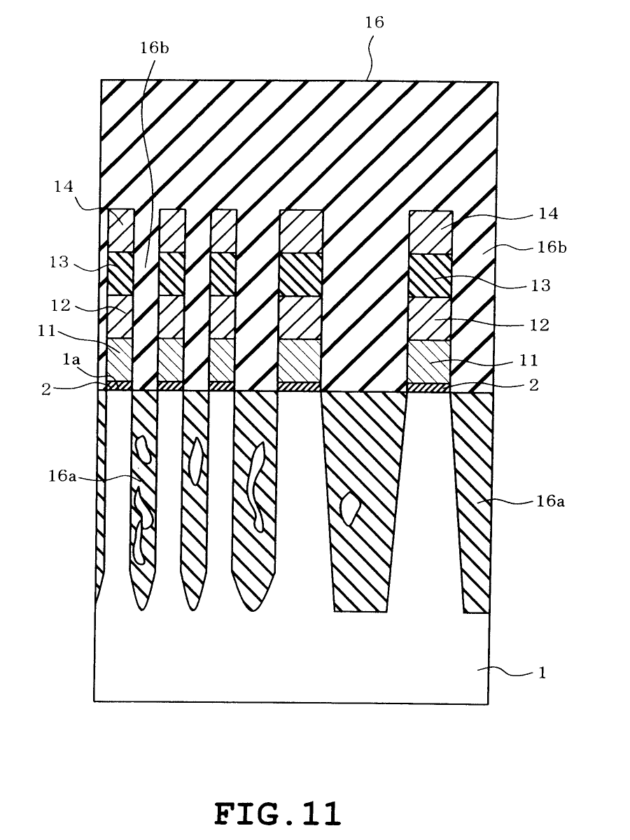

Subsequently, the aforesaid element isolation trenches 15 are filled with an insulating film such as a silicon oxide film by the thermal CVD method. The following describes a specific deposition condition of the thermal CVD method. TEOS, ozone O₃ and water vapor H₂O are used as material gases. The material gases are set to flow rates of 2.4 g/min, 27 slm and 8 g/min respectively and the deposition temperature is set to 375° C., for the reason as described in the first embodiment. The deposition time is controlled so that a thermal CVD film 16 (a silicon oxide film) is formed, as shown in FIG. 11. The thermal CVD film 16 is formed so as to reach an upper part of the silicon oxide film 14, thereafter completing the filling of the element isolation trenches 15.

The film 16a of the above-described silicon oxide film 16 has a rough surface as in the first embodiment. A part of each trench which is level with or is located lower than the upper surface 1a of the silicon substrate 1 is filled with the silicon oxide film 16a having a porosity of about 13%, for the same reason as described above in the first embodiment. On the other hand, the insulating film filling a part of each trench 15 located higher than the upper surface 1a of the silicon substrate 1 is denser (a porosity of substantially 0%, for example). Even when the plural element isolation trenches 15 differ from one another in the width or the cubic volume, the silicon oxide film 16b is deposited so as to have a substantially uniform height. As a result, deformation of the active area and deterioration of electrical characteristics can be suppressed in the same manner as in the first embodiment.

Furthermore, the conditions such as the flow rates of the material gases and the deposition temperature are changed in the formation of the thermal CVD film 16 (16a and 16b) so that the porosity of the film 16a which is level with or is located lower than the upper surface 1a of the silicon substrate 1 is varied. As a result, since the stress of the film 16a is not rendered sufficiently small when the porosity is less than 5% as in the first embodiment, deformation of the active area, deterioration of the electrical characteristics and the like are observed.

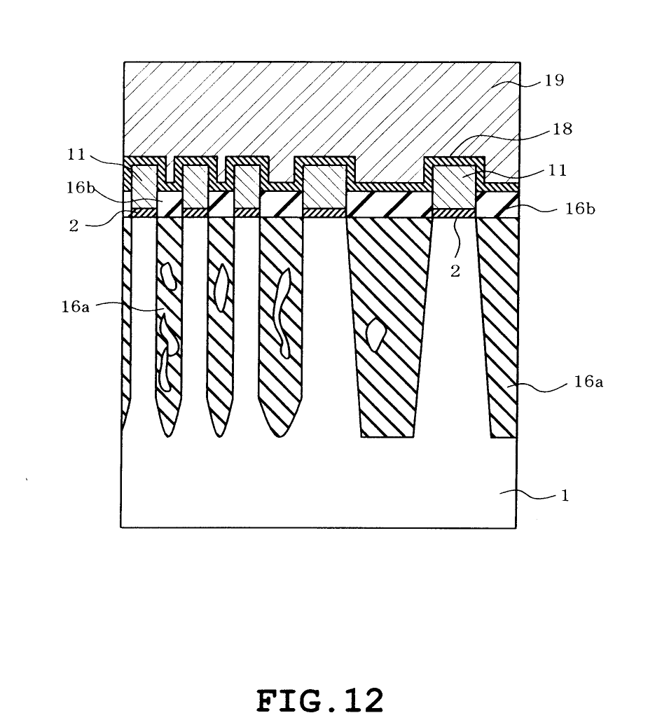

After the fabrication process has advanced to the state as shown in FIG. 11, planarization by the (CMP) process is carried out. The processing sacrificial film is removed by the wet treatment, and the element isolation region is etched back and other treatments are carried out. Furthermore, an electrode block film 18 and a gate electrode 19 are formed (see FIG. 12). Additionally, a diffusion layer, contact holes, a wiring layer and the like are consecutively formed, whereupon the semiconductor memory device is fabricated.

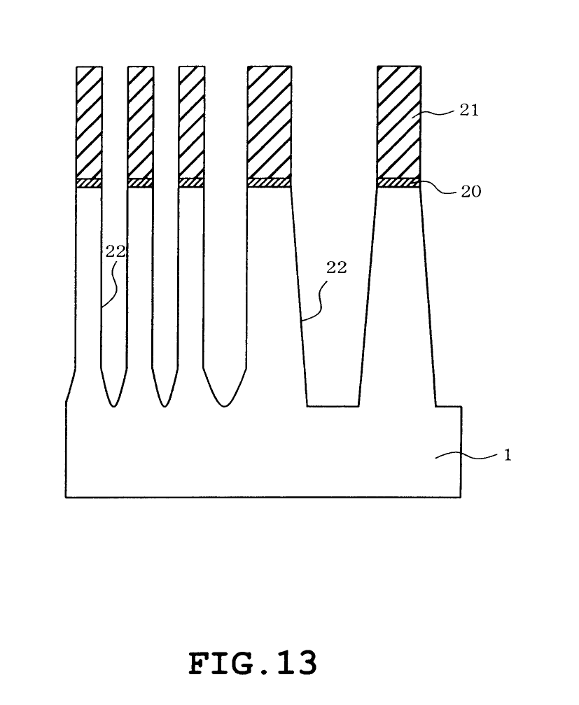

FIGS. 13 to 15 illustrate a third embodiment. In the third embodiment, identical or similar parts are labeled by the same reference symbols as those in the first embodiment. The third embodiment is directed to the case where element isolation trenches of a logic device are filled with an insulating film.

A process of forming element isolation trenches of the logic device will first be described with reference to FIG. 13. As shown, a silicon oxide film 20 formed into a sacrificial oxide film and a silicon nitride film 21 serving as a processing sacrificial film are formed on the silicon substrate 1 in turn, so that element isolation trenches 22 are formed by the lithography process and the RIE process.

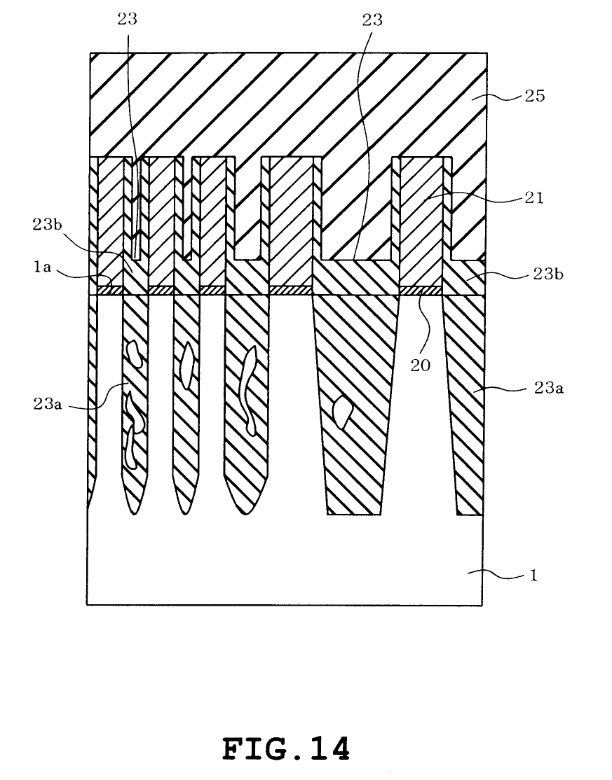

Subsequently, the aforesaid element isolation trenches 22 are filled with an insulating film such as a silicon oxide film by the thermal CVD method. The following describes a specific deposition condition of the thermal CVD method. TEOS, O₃ and water vapor H₂O are used as material gases. The material gases are set to flow rates of 2 g/min, 27 standard liter/minute (slm) and 4 g/min respectively. A deposition temperature is set to 300° C. A thermal CVD film (a silicon oxide film) 23 (23a and 23b) is then formed by controlling the deposition time as shown in FIG. 14, so that the thermal CVD film 23 reaches part of the height of the silicon nitride film 21.

The film 23a of the above-described silicon oxide film (the thermal CVD film) 23 has a rough surface as in the first embodiment. A part of each trench 22 which is level with or is located lower than the upper surface 1a of the silicon substrate 1 is filled with the silicon oxide film 23a having a porosity of about 9%, for the same reason as described above in the first embodiment. On the other hand, the silicon oxide film 23b filling a part of each trench 22 located higher than the upper surface 1a of the silicon substrate 1 is denser (a porosity of substantially 0%, for example). Even when the plural element isolation trenches 22 differ from one another in the width or the cubic volume, the silicon oxide film 23b is deposited so as to have a substantially uniform height. As a result, deformation of the active area and deterioration of electrical characteristics can be suppressed in the same manner as in the first embodiment.

Furthermore, the conditions such as the flow rates of the material gases and the deposition temperature are changed in the formation of the thermal CVD film 23 so that the porosity of the film 23a which is level with or is located lower than the upper surface 1a of the silicon substrate 1 is varied. As a result, since the stress of the film 23a is not rendered sufficiently small when the porosity is less than 5% as in the first embodiment, deformation of the active area, deterioration of the electrical characteristics and the like are observed.

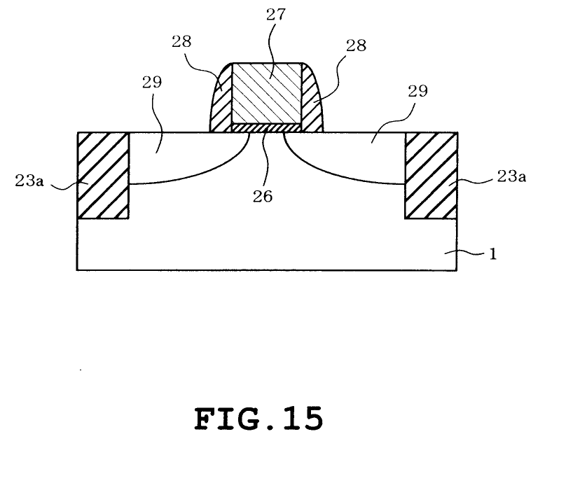

After the element isolation trenches 22 have been filled with the thermal CVD film 23 as described above, an RIE process, a hydrofluoric acid treatment and annealing are carried out, and a silicon oxide film 25 is further formed on the film 23b which is deposited by the thermal CVD method, by an HDP-CVD method and caused to fill the trenches 22 (see FIG. 14). Subsequently, planarization by the CMP process is carried out. The processing sacrificial film is removed by the wet treatment, and the element isolation region is etched back and other treatments are carried out. Furthermore, a gate insulating film 26, a gate electrode 27, a sidewall spacer 28 and a diffusion layer 29 are formed (see FIG. 15), whereupon a transistor (the logic device) is fabricated.

The foregoing embodiments are not restrictive and can be modified or expanded as follows. For example, although the polysilicon film is formed as the charge storage film in the first embodiment, the element isolation trenches can be filled with the insulating film by the similar thermal CVD method even when the charge storage film is an amorphous silicon film. Furthermore, although having a charge trapping type cell structure (referred to as “MONOS”) in the second embodiment, the flash memory may have another cell structure (referred to as “SONOS”). Furthermore, the above-described configurations may be applied more effectively to all the devices in which an intercell distance is not more than 40 nm half pitch, at which value the mechanical strength of the active area is significantly reduced.

The foregoing description and drawings are merely illustrative of the principles and are not to be construed in a limiting sense. Various changes and modifications will become apparent to those of ordinary skill in the art. All such changes and modifications are seen to fall within the scope as defined by the appended claims.

What is claimed is:

1. A method of fabricating a semiconductor device, comprising:
forming, on a silicon substrate, a film to be processed selected at least from a polysilicon film, an amorphous silicon film, a silicon oxide film and a silicon nitride film;
forming an element isolation trench by processing the silicon substrate and the film to be processed; and
filling the element isolation trench with an insulating film by a thermal chemical vapor deposition (CVD) method,
wherein the thermal CVD method in filling the trench is executed under a film forming condition that the insulating film filling a part of the trench that is level with or is located lower than an upper surface of the silicon substrate has a porosity set so as to be not less than 5% and that the insulating film filling a part of the trench located higher than the upper surface of the silicon substrate has a lower deposition rate than the insulating film filling said part of the trench that is level with or is located lower than the upper surface of the silicon substrate.

2. The method according to claim 1, wherein the thermal CVD method uses a material gas including tetraethyl orthosilicate (TEOS), ozone (O₃) and water vapor (H₂O).

3. The method according to claim 2, wherein in the thermal CVD method, the tetraethyl orthosilicate is set to a flow rate ranging from 0.3 to 5 g/min, the ozone is set to a flow rate ranging from 5 to 50 slm and the water vapor is set to a flow rate not less than 1 g/min, and a deposition temperature is set in a range from 250 to 400° C.

4. The method according to claim 1, wherein the film to be processed is made by forming a tunnel insulating film, a polysilicon film and a silicon nitride film in sequence.

5. The method according to claim 4, wherein the insulating film is formed so as to reach part of the polysilicon film.

6. The method according to claim 5, wherein after filling the trench with the insulating film by the thermal CVD method, the trench is filled with a polysilazane film by a coating method.

7. The method according to claim 5, wherein after filling the trench with the insulating film by the thermal CVD method, the trench is filled with a high density plasma chemical vapor deposition (HDP-CVD) film by an HDP-CVD method.

8. The method according to claim 1, wherein the film to be processed is made by forming a tunnel insulating film, a silicon nitride film, a silicon oxide film, a silicon nitride film and a silicon oxide film in sequence.

9. The method according to claim 8, wherein the insulating film is formed so as to reach an upper part of the uppermost silicon oxide film of the film to be processed.

10. The method according to claim 1, wherein the film to be processed is made by forming a silicon oxide film and a silicon nitride film in turn.

11. The method according to claim 1, wherein the element isolation trench includes a plurality of the element isolation trenches having different widths, and the insulating film is deposited by the thermal CVD method so as to have a substantially uniform height between or among the element isolation trenches.

12. The method according to claim 1, wherein under said film forming condition of the thermal CVD method, the insulating film filling the part of the trench located higher than the upper surface of the silicon substrate is denser than the insulating film filling the part of the trench that is level with or is located lower than the upper surface of the silicon substrate.

13. The method according to claim 12, wherein the insulating film filling the part of the trench located higher than the upper surface of the silicon substrate has a porosity set substantially to 0%.

14. The method according to claim 1, wherein the porosity of the insulating film filling the part of the trench that is level with or is located lower than the upper surface of the silicon substrate has an upper limit of about 25%.

15. A semiconductor device comprising:
a silicon substrate;
a tunnel insulating film formed on the silicon substrate;
a charge storage film formed on the tunnel insulating film;
a plurality of element isolation trenches formed by processing the silicon substrate, the tunnel insulating film and the charge storage film; and
an insulating film filling the element isolation trenches by a thermal chemical vapor deposition method, wherein:
the insulating film includes a first insulating film filling a part of the trenches that is level with or is located lower than an upper surface of the silicon substrate and a second insulating film filling a part of the trenches located higher than the upper surface of the silicon substrate;
the second insulating film has a substantially uniform height from the upper surface of the silicon substrate between the element isolation trenches; and
the first insulating film has a smaller density than the second insulating film.

16. The device according to claim 15, wherein the first insulating film has a porosity that is set so as to be not less than 5%.

17. The device according to claim 15, wherein the first insulating film has a porosity that is set so as to be not more than 25%.

18. The device according to claim 15, wherein the second insulating film has a porosity that is set so as to be substantially 0%.

19. The device according to claim 15, wherein the silicon substrate includes an active area which is located between the element isolation trenches and has a width set so as to be not more than 40 nm.

20. The device according to claim 15, wherein the silicon substrate includes an active area which is located between the element isolation trenches and has a distortion angle that is not more than 5°.
